(19) United States
(12) Patent Application Publication
(10) Pub. No.: US 2016/0109620 A1
(43) Pub. Date: Apr. 21, 2016

(54) NANOSTRUCTURE

(71) Applicant: Dexerials Corporation, Tokyo (JP)

(72) Inventor: Sohmei ENDOH, Utsunomiya-shi (JP)

(73) Assignee: DEXERIALS CORPORATION, Tokyo (JP)

(21) Appl. No.: 14/442,502

(22) PCT Filed: Jan. 24, 2014
(86) PCT No.: PCT/JP2014/051515

§ 371 Date: May 13, 2015

(30) Foreign Application Priority Data
Feb. 6, 2013 (JP) 2013-021342

(51) Int. Cl. G02B 1/118; G03F 7/00; G03F 7/20

(52) U.S. Cl. CPC G02B 1/118; G03F 7/2053; G03F 7/0002

(57) ABSTRACT

A coded nanostructure has a structure having a number of rows of tracks, each including arrangement of structures formed by protrusions or depressions on a surface of a substrate. Coding is achieved by wobble of the arrangement of the structures in an extending direction of the tracks.

### TECHNICAL FIELD

The present invention relates to a coded nanostructure.

### BACKGROUND ART

A nanostructure in which structures formed by protrusions or depressions on a surface of a substrate are arranged at a fine pitch, which is smaller than or equal to a visible wavelength, in a number of rows has been known as a moth-eye structure, which exhibits an excellent antireflection effect against light in a visible wavelength range, and used as an optical element such as an antireflection film.

With regard to nanostructures having a moth-eye performance, modulating arrangement of structures constituting such a nanostructure with a sine wave or a triangular wave so as to cause wobble in order to prevent unevenness in appearance from occurring has been known (Patent Literature 1).

### CITATION LIST

### Patent Literature

Patent Literature 1: Japanese Patent No. 4535199

### SUMMARY OF INVENTION

### Technical Problem

Meanwhile, replicas of a nanostructure can be easily manufactured by transferring surface concavities and convexities of a product used as a template. Thus, it is desirable to code a production management code, a lot number, or the like, in the nanostructure.

Methods of manufacturing nanostructures may include a method including: first exposing with laser light, and then developing, a master having a resist layer provided on a surface thereof to pattern the resist layer on the surface of the master; subsequently etching the master with the patterned resist layer used as a mask to form surface concavities and convexities on the master; and transferring the surface concavities and convexities to a resin material. Moreover, in a nanostructure, individual structures need to be densely arranged in a tetragonal lattice or a hexagonal lattice, for example. Thus, intensity modulation of the laser light for exposing the master with a coding signal can be considered as a coding method in a nanostructure.

However, when the laser light for exposing the master is intensity-modulated, the diameters of the individual structures arranged at a predetermined pitch vary, thus reducing the packing density of the structures. Alternatively, a pitch between tracks (track pitch), each of which is the arrangement of the individual structures in an exposure direction, needs to be adjusted, thus complicating the manufacturing method.

Although coding with the use of the wobble technique described in Patent Literature 1 can be considered, it is difficult to code a production management code, a lot number, or the like, simply by modulating arrangement of individual structures constituting a moth-eye structure with a sine wave or a triangular wave.

In contrast to this, it is an object of the present invention to provide a nanostructure coded by a simple method.

### Solution to Problem

In order to solve the above problem, the present invention provides a nanostructure including a number of rows of tracks, each including arrangement of structures formed by protrusions or depressions on a surface of a substrate, in which coding is achieved by wobble of the arrangement of the structures in an extending direction of the tracks.

Moreover, the present invention provides a method of manufacturing the above-described nanostructure, the method including the steps of:

forming a resist layer on a surface of a master;

pulse-irradiating the resist layer on the master with laser light while moving an irradiation position thereof to form a latent image pattern in which a number of rows of tracks, each including arrangement of spot-like latent images made of exposed portions with a fine pitch in an exposure direction, are arranged;

developing the latent images to form a resist pattern;

etching the master with the resist pattern used as a mask to form a concave-convex pattern on the surface of the master; and

transferring surface concavities and convexities of the master to a resin material. In the step of forming the latent image pattern, the laser light is deflected so that the tracks are wobbled in an extending direction of the tracks.

### Advantageous Effects of Invention

According to the nanostructure of the present invention, the arrangement of the structures is wobbled in the extending direction of the tracks. According to a cycle and an amplitude of such wobble, a production management code, a lot number, or the like, can be coded.

### BRIEF DESCRIPTION OF DRAWINGS

A in FIG. 1 is a schematic plan view illustrating a nanostructure according to an embodiment; B is a partial enlarged plan view illustrating the nanostructure illustrated in A; C is a cross-sectional view thereof in tracks T1 and T3 in B; D is a cross-sectional view thereof in tracks T2 and T4 in B; E is a schematic waveform chart illustrating a modulated waveform of laser light for forming latent images corresponding to the tracks T1 and T3 in B in the manufacturing of a nanostructure master; and F is a schematic waveform chart illustrating a modulated waveform of laser light for forming latent images corresponding to the tracks T2 and T4 in B in the manufacturing of the nanostructure master.

FIG. 2 is a diagram for explaining coding according to an embodiment.

FIG. 3 is a diagram for explaining coding according to an embodiment.

FIG. 4 is a schematic diagram for explaining a roll master exposure apparatus.

### DESCRIPTION OF EMBODIMENTS

The present invention will now be described in detail with reference to the drawings.

A in FIG. 1 is a schematic plan view illustrating a nanostructure 1 according to an embodiment of the present invention; B is a partial enlarged view thereof; C is a cross-sectional view thereof in tracks T1 and T3 in B; and D is a cross-sectional view thereof in tracks T2 and T4 in B. This nanostructure 1 has a moth-eye structure in which each of tracks T1, T2, T3, . . . includes structures 3, which are formed by protrusions on a surface of a substrate 2, arranged at a predetermined fine pitch P1 and a large number of such tracks are arranged at a predetermined track pitch Tp. Note that the nanostructure of the present invention is not limited to the moth-eye structure but includes wire grids, nanogroove wave plates, nanogroove filters, and structural color devices, for example.

The size of the fine pitch P1 of the structures 3 can be set, for example, at a visible wavelength or less, more specifically, at about 300 nm or less. The size can be set at 1000 nm or less depending on its intended use.

The substrate 2 may be made of a transparent synthetic resin, such as polycarbonate (PC) or polyethylene terephthalate (PET), or glass.

The substrate 2 may be in the form of a film, a sheet, a plate, or a block, for example.

In the nanostructure 1, arrangement pitches of the structures 3 are shifted from each other by a half pitch between two adjacent ones of the tracks T1, T2, T3, and T4. Consequently, the structures 3 in the two adjacent ones of the tracks T1, T2, T3, and T4 are arranged in a staggered manner and the arrangement pattern of the structures 3 thus forms a quasi-hexagonal lattice pattern as illustrated in B of FIG. 1. Note that the arrangement pattern of the structures in the present invention is not limited to such a quasi-hexagonal lattice. The arrangement pattern may be a regular hexagonal lattice, a regular tetragonal lattice, or a quasi-tetragonal lattice. The quasi-hexagonal lattice as used herein refers to a distorted pattern obtained by stretching a regular hexagonal lattice in an extending direction of the tracks T1, T2, T3, and T4 (an x-direction in FIG. 1). The quasi-tetragonal lattice as used herein refers to a distorted pattern obtained by stretching a regular tetragonal lattice in the extending direction of the tracks T1, T2, T3, and T4 (the x-direction in FIG. 1).

Note that the shape itself of the individual structure 3 has no particular limitations in the present invention. The structure 3 may have a conical structure having a circular, elliptical, oval, or egg-shaped bottom surface. Alternatively, the bottom surface of the structure 3 may be formed as a circle, an ellipse, an oval, or an egg shape, and the top thereof may be formed as a curved surface or a flat surface. Moreover, a minute protrusion may be provided between adjacent ones of the structures 3.

The height of each structure 3 also has no particular limitations. For example, the height may be in a range of about 180 nm to about 420 nm.

The structures 3 can be provided by forming protrusions or depressions on the surface of the substrate 2.

The nanostructure 1 of the present embodiment has a feature in that manufacturer's identification information, management information, or the like is coded by wobble of the arrangement of the structures 3 in the extending direction of the tracks T1, T2, T3, . . . . More specifically, when the nanostructure 1 is observed in the extending direction of the tracks T1, T2, T3, . . . , the nanostructure 1 includes a wobbled region R1, a non-wobbled region R2, a wobbled region R3, and a non-wobbled region R4 sequentially formed. The wobbled region R1 corresponds to one cycle of a sine wave having a predetermined amplitude. The wobbled region R3 corresponds to two cycles of a sine wave having a larger amplitude and a longer cycle than the wobbled region R1. In this nanostructure 1, the presence and absence of a region where the arrangement of the structures 3 is wobbled, a position of such a wobbled region in the track arrangement direction, a wobbling cycle (wavelength) thereof, and a wobbling amplitude thereof are appropriately changed as described above, thereby coding manufacture's identification information, management information, or the like in the nanostructure 1.

Moreover, the phases of the tracks T1, T2, T3, . . . coincide with one another also in the wobbled regions R1 and R3 in the nanostructure 1. Consequently, no reduction in the packing density of the structures 3 in the nanostructure 1 is caused by the wobble of the arrangement of the structures 3. Thus, no deterioration in performance would occur if the nanostructure 1 is used as a moth-eye structure.

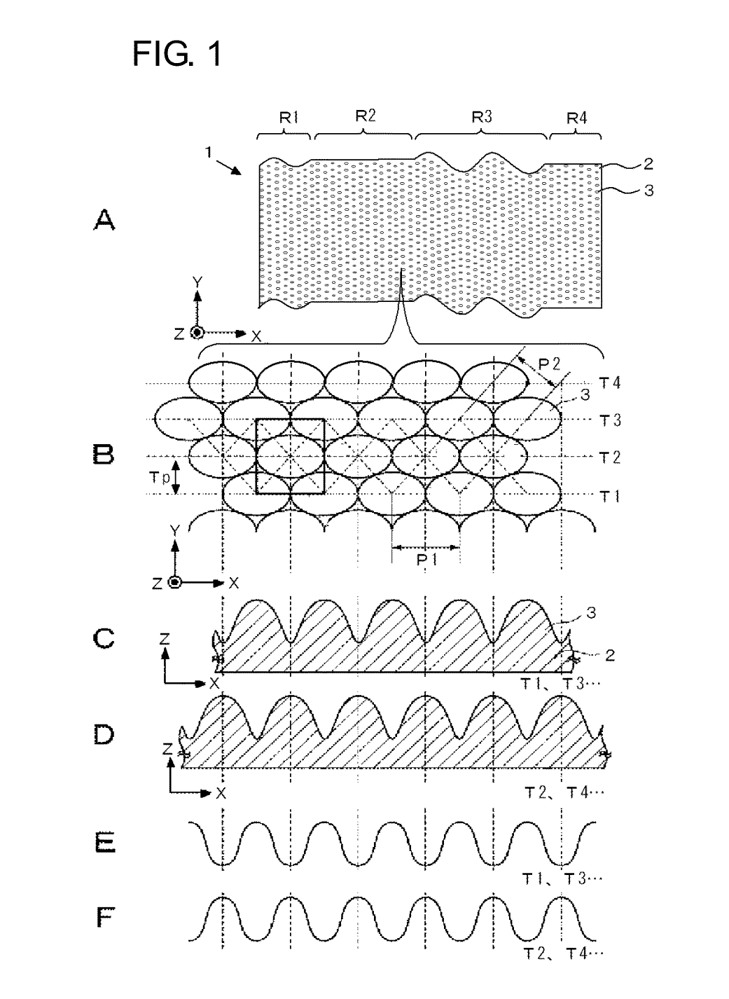

In the present invention, the arrangement of the structures 3 can take various wobble forms to achieve coding in the nanostructure. For example, a nanostructure 1B according to an embodiment illustrated in FIG. 2 includes the structures 3 formed in tetragonal lattice arrangement. For coding, tracks are synchronized and wobbled with a sine wave in entire region in the track extending direction. More specifically, a region 1A formed by 1.5 cycles of a sine wave having a predetermined cycle and a predetermined amplitude; a region 2A formed by 2.5 cycles of a sine wave having a shorter cycle and a larger amplitude than the region 1A; and a region 3A formed by one cycle of a sine wave having the same cycle as the region 2A and having an even larger amplitude than the region 2A are continuously formed.

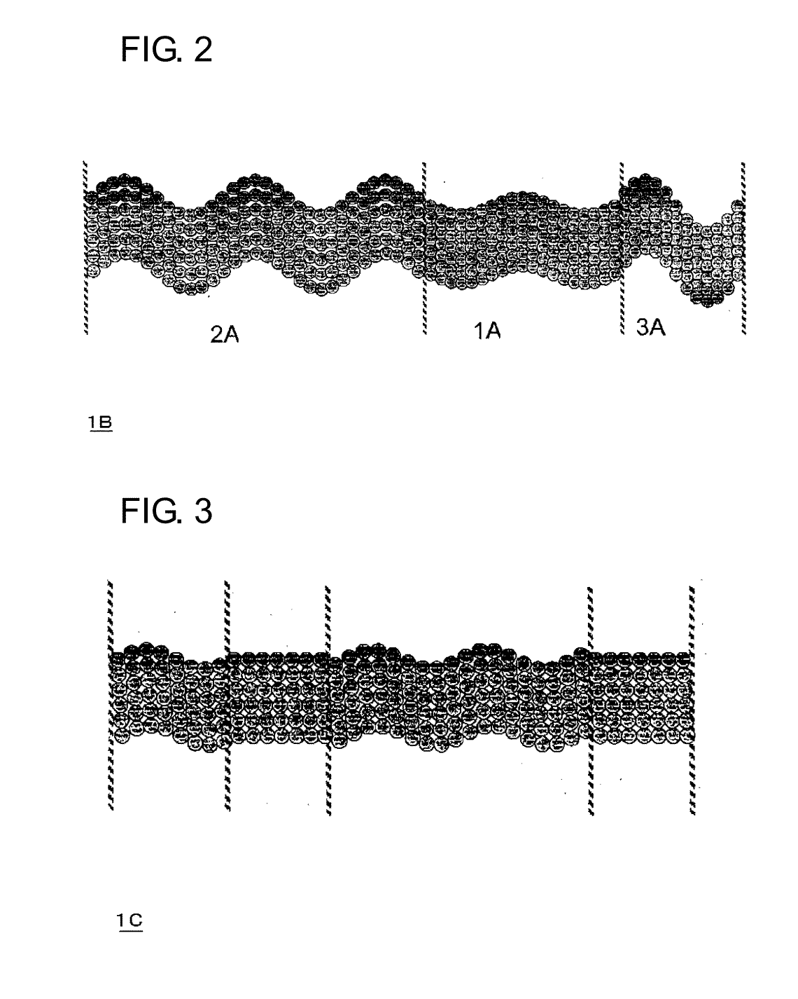

A nanostructure 1C illustrated in FIG. 3 is formed by: a wobbled region for one cycle of a sine wave; a region without wobble; and a wobbled region for two cycles of the sine wave. As just described, coding may be performed by such intermittent arrangement of wobbled regions having the same waveform.

When providing wobble in the track extending direction in the arrangement of the structures 3, an amplitude of such wobble is typically in a range of ±10 nm to ±1 μm and a length for one cycle of such wobble in its extending direction is in a range of 1 to 50 μm in the nanostructure of the present invention.

The nanostructure of the present invention can be manufactured by deflecting laser light in a step of forming a latent image pattern in a method of manufacturing a known nanostructure having no coding regions so that the latent image pattern is wobbled according to a coding signal. More specifically, the nanostructure of the present invention can be manufactured by:

a step of forming a resist layer on a surface of a master;

a step of pulse-irradiating the resist layer on the master with laser light while moving its irradiation position to form a latent image pattern in which a number of rows of tracks, each including arrangement of spot-like latent images made of exposed portions with a fine pitch in an exposure direction, are arranged, the laser light being deflected so that the tracks are wobbled in an extending direction of the tracks;

a step of developing the latent images to form a resist pattern;

a step of etching the master with the resist pattern used as a mask to form a concave-convex pattern on the surface of the master; and

a step of transferring surface concavities and convexities of the master to a resin material.

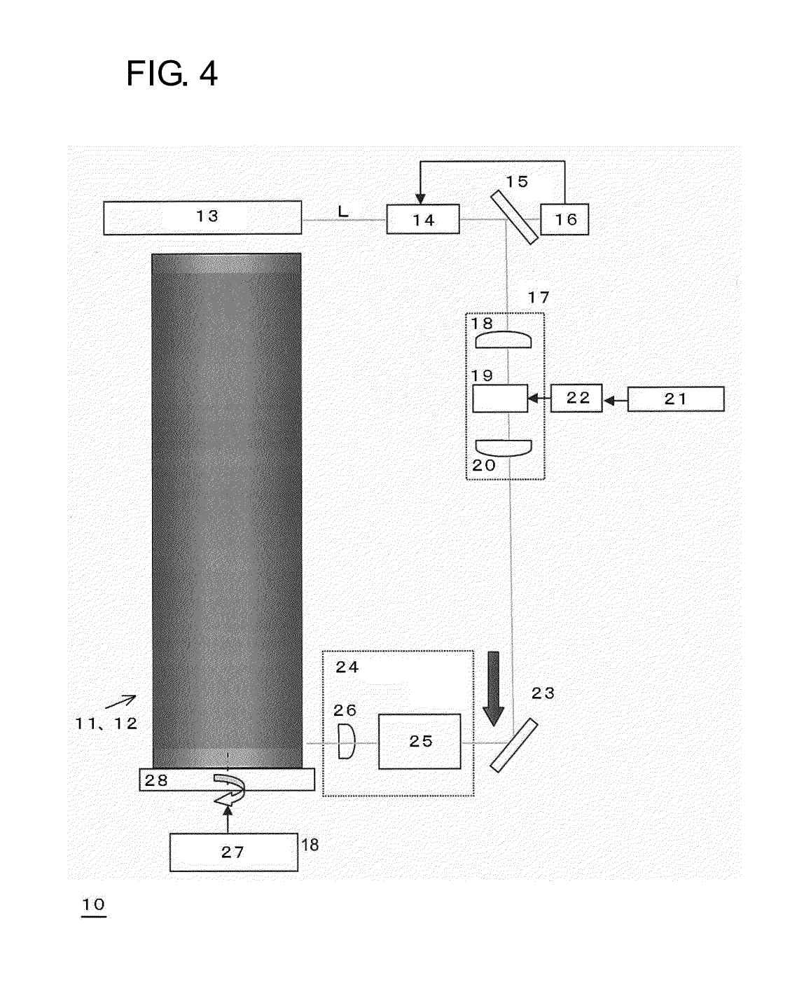

FIG. 4 is a schematic diagram for explaining a roll master exposure apparatus 10 suitable for forming a latent image pattern. The roll master exposure apparatus 10 includes: a laser light source 13 that emits laser light (wavelength: 266 nm) for exposing a resist layer 12 deposited on a surface of a roll master 11; an electro optical modulator (EOM) 14 on which laser light L exited from the laser light source 13 is incident; a mirror 15 constituted by a polarizing beam splitter; and a photodiode 16. A polarized component transmitted through the mirror 15 is received at the photodiode 16. The photodiode 16 controls the electro optical modulator 14 to modulate the phase of the laser light L and thereby reduce laser noise to ±1% or less.

Additionally, the roll master exposure apparatus 10 includes an optical modulation and deflection system (OM/OD) 17 that modulates the intensity of the phase-modulated laser light L and deflects the laser light. The optical modulation and deflection system (OM/OD) 17 includes: a condenser lens 18; an acoustic-optical modulator/acoustic-optical deflector (AOM/AOD) 19; and a lens 20 that produces parallel light.

Additionally, the roll master exposure apparatus 10 includes: a formatter 21 that forms a two-dimensional latent image pattern; and a driver 22. The formatter 21 controls irradiation timing of laser light to the resist layer 12. The driver 22 controls the acoustic-optical modulator/acoustic-optical deflector (AOM/AOD) 19 to modulate the laser light.

More specifically, when such a two-dimensional latent image pattern is formed, the formatter 21 generates a polarity reversal formatter signal and a signal for synchronizing a rotation controller of the roll master 11 for every track, and the AOM/AOD 19 performs intensity modulation. Exposure at a constant angular velocity (CAV) and with an appropriate rotation speed and an appropriate modulation frequency allows spot-like latent images, each having a predetermined size, to be formed at a predetermined pitch. Also, the formatter 21 supplies a signal for causing the laser light to be wobbled to the driver 22. The AOM/AOD 19 controls the irradiation direction of the laser light by one type of frequency modulation or amplitude modulation with the use of a sine wave or a burst wave, for example, or an appropriate combination thereof, thereby forming wobble in the exposure direction in the two-dimensional latent image pattern.

When a latent image pattern with a hexagonal lattice is formed, for example, a pitch in the circumferential direction of the roll master 11 (i.e., a pitch P1 in the exposure direction) is set at 315 nm, a diagonal pitch P2 in a direction of about 60 degrees (direction of about −60 degrees) with respect to the circumferential direction is set at 300 nm, and a feed pitch Tp is set at 251 nm (the Pythagorean theorem). In this case, the rotation speed of the roll master 11 is set at 1800, 900, or 450 rpm, for example. The frequency of the polarity reversal formatter signal to be generated by the formatter 21 is determined according to this rotational speed. Latent images with a quasi-hexagonal lattice, tetragonal lattice, or quasi-tetragonal lattice pattern can also be formed in a similar manner.

The laser light intensity-modulated by the AOM/AOD 19 and deflected according to the signal for causing the laser light to be wobbled is reflected by a mirror 23, shaped into a desired beam shape by a beam expander (BEX) 25 on a movable table 24, and irradiated onto the resist layer 12 on the roll master 11 via an objective lens 26. More specifically, the laser light is expanded to have a five-times-larger beam diameter by the beam expander 25 and irradiated onto the resist layer 12 on the roll master 11 via the objective lens 26 having a numerical aperture (NA) of 0.9, for example.

The roll master 11 is placed on a turntable 28 connected to a spindle motor 27. The resist layer 12 is subjected to pulse irradiation with laser light while the roll master 11 is rotated and the laser light is moved in a height direction. The latent images thus formed on the resist layer 12 by the irradiation each have a generally elliptical shape having its long axis in the circumferential direction.

Although the method of forming the latent image pattern on the resist layer 12 with the roll master exposure apparatus 10 has been described above, such a latent image pattern may be formed by exposure on a disk master in the method of manufacturing the nanostructure of the present invention.

After the formation of the latent image pattern, the resist layer 12 is developed to form a resist pattern by dissolving the exposed portions of the resist.

Next, the master is etched with the resist pattern used as a mask to form a concave-convex pattern on the surface of the master. Such patterning is done by plasma etching in a CHF₃ gas atmosphere, for example.

The thus formed master with the surface having the fine concave-convex pattern is made close contact with a UV resin material such as an acrylic sheet. The resin material is then cured by ultraviolet irradiation, for example. Peeling off of the resin material yields a nanostructure to which the fine concavities and convexities on the surface of the master have been transferred. Here, if a roll master is employed as a master, a large sheet of coded nanostructure can be produced by a roll-to-roll method.

The nanostructure of the present invention can preferably be used in various optical devices such as displays, optical electronics, optical communications (optical fibers), solar cells, and lighting apparatuses to obtain a function achieved by the nanostructure.

Depending on the intended use of the nanostructure, a transparent conductive film made of ITO (In₂O₃, SnO₂: indium tin oxide), AZO (Al₂O₃, ZnO: aluminum-doped zinc oxide), SZO, FTO (fluorine-doped tin oxide), SnO₂ (stannic oxide), GZO (gallium-doped zinc oxide), or IZO (In₂O₃, ZnO: indium zinc oxide), for example, may be formed on the surface of the nanostructure. In such a case, the transparent conductive film is preferably formed in conformity with the surface concavities and convexities of the nanostructure. The transparent conductive film can be formed by sputtering, wet coating, or the like.

### REFERENCE SIGNS LIST

1, 1B, 1C nanostructure
2 substrate
3 structure
10 roll master exposure apparatus
11 roll master
12 resist layer
13 laser light source
14 electro optical modulator (EOM)
15 mirror
16 photodiode
17 optical modulation and deflection system (OM/OD)
18 condenser lens
19 acoustic-optical modulator/acoustic-optical deflector (AOM/AOD)
20 lens
21 formatter
22 driver
23 mirror
24 movable table
25 beam expander (BEX)
26 objective lens
27 spindle motor
28 turntable
L laser light
P1 pitch (in the exposure direction)
P2 diagonal pitch
R1, R3 wobbled region
R2, R4 non-wobbled region
T1, T2, T3, T4 track
Tp track pitch or feed pitch

1. A nanostructure comprising a number of rows of tracks, each including arrangement of structures formed by protrusions or depressions on a surface of a substrate, wherein coding is achieved by wobble of the arrangement of the structures in an extending direction of the tracks.

2. The nanostructure according to claim 1, wherein a wobbled region is provided to part of or entire region when the nanostructure is observed in the extending direction of the tracks.

3. The nanostructure according to claim 1, wherein the coding is achieved by a wobbling cycle or a wobbling amplitude.

4. The nanostructure according to claim 1, wherein phases of the wobbles of the tracks coincide with one another.

5. A method of manufacturing the nanostructure according to claim 1, the method including the steps of:
forming a resist layer on a surface of a master;
pulse-irradiating the resist layer on the master with laser light while moving an irradiation position thereof to form a latent image pattern in which a number of rows of tracks, each including arrangement of spot-like latent images made of exposed portions with a fine pitch in an exposure direction, are arranged;
developing the latent images to form a resist pattern;
etching the master with the resist pattern used as a mask to form a concave-convex pattern on the surface of the master; and
transferring surface concavities and convexities of the master to a resin material, wherein
in the step of forming the latent image pattern, the laser light is deflected so that the tracks are wobbled in an extending direction of the tracks.

6. The method of manufacturing the nanostructure according to claim 5, the pulse-irradiation of the laser light is wobbled by an optical modulation and deflection system.

7. The nanostructure according to claim 2, wherein the coding is achieved by a wobbling cycle or a wobbling amplitude.

8. The nanostructure according to claim 2, wherein phases of the wobbles of the tracks coincide with one another.

9. The nanostructure according to claim 3, wherein phases of the wobbles of the tracks coincide with one another.

10. The nanostructure according to claim 7, wherein phases of the wobbles of the tracks coincide with one another.

11. A method of manufacturing the nanostructure according to claim 2, the method including the steps of:
forming a resist layer on a surface of a master;
pulse-irradiating the resist layer on the master with laser light while moving an irradiation position thereof to form a latent image pattern in which a number of rows of tracks, each including arrangement of spot-like latent images made of exposed portions with a fine pitch in an exposure direction, are arranged;
developing the latent images to form a resist pattern;
etching the master with the resist pattern used as a mask to form a concave-convex pattern on the surface of the master; and
transferring surface concavities and convexities of the master to a resin material, wherein
in the step of forming the latent image pattern, the laser light is deflected so that the tracks are wobbled in an extending direction of the tracks.

12. A method of manufacturing the nanostructure according to claim 3, the method including the steps of:
forming a resist layer on a surface of a master;
pulse-irradiating the resist layer on the master with laser light while moving an irradiation position thereof to form a latent image pattern in which a number of rows of tracks, each including arrangement of spot-like latent images made of exposed portions with a fine pitch in an exposure direction, are arranged;
developing the latent images to form a resist pattern;
etching the master with the resist pattern used as a mask to form a concave-convex pattern on the surface of the master; and
transferring surface concavities and convexities of the master to a resin material, wherein
in the step of forming the latent image pattern, the laser light is deflected so that the tracks are wobbled in an extending direction of the tracks.

13. A method of manufacturing the nanostructure according to claim 7, the method including the steps of:
forming a resist layer on a surface of a master;
pulse-irradiating the resist layer on the master with laser light while moving an irradiation position thereof to form a latent image pattern in which a number of rows of tracks, each including arrangement of spot-like latent images made of exposed portions with a fine pitch in an exposure direction, are arranged;
developing the latent images to form a resist pattern;
etching the master with the resist pattern used as a mask to form a concave-convex pattern on the surface of the master; and
transferring surface concavities and convexities of the master to a resin material, wherein
in the step of forming the latent image pattern, the laser light is deflected so that the tracks are wobbled in an extending direction of the tracks.

14. The method of manufacturing the nanostructure according to claim 11, the pulse-irradiation of the laser light is wobbled by an optical modulation and deflection system.

15. The method of manufacturing the nanostructure according to claim 12, the pulse-irradiation of the laser light is wobbled by an optical modulation and deflection system.

16. The method of manufacturing the nanostructure according to claim 13, the pulse-irradiation of the laser light is wobbled by an optical modulation and deflection system.
